(19) United States
(12) Patent Application Publication
(10) Pub. No.: US 2026/0064930 A1
(43) Pub. Date: Mar. 5, 2026

(54) POLARITY INVERTER REMOVAL FOR REDUCING WIRE CONGESTION

(71) Applicant: International Business Machines Corporation, Armonk, NY (US)

(72) Inventors: Nathaniel Douglas Hieter, Clinton Corners, NY (US); Seth Knickerbocker, Stanfordville, NY (US); Frank J. Musante, Poughkeepsie, NY (US); Alexander Joel Suess, Hopewell Junction, NY (US); Ying Zhou, Austin, TX (US)

(21) Appl. No.: 18/815,938

(22) Filed: Aug. 27, 2024

(51) Int. Cl. G06F 30/394; G06F 30/327

(52) U.S. Cl. CPC G06F 30/394; G06F 30/327

(57) ABSTRACT

A system is provided to fabricate an integrated circuit. The system generates a first netlist that includes an initial logic design defined connections between source gates, inverters, and sink gates using a total number of wires. Each of the connections establish a polarity that defines an overall polarity. The system further performs a polarity inverter removal process that removes at least one inverter from at least one connection and changes the corresponding polarity of the at least one connection from a first polarity to a second polarity. The system performs a wire placement based at least in part on the first netlist having the at least one inverter removed to build inverter trees with the overall polarity. The system further performs an inverter restoration operation that restores the first polarity of the at least one connection and produces a second netlist that reduces the overall wire length.

### BACKGROUND

The present disclosure relates to integrated circuit (IC) design, and more specifically, to methods and systems configured to perform polarity inverter removal for reducing wire congestion in an IC.

A netlist topology (often times simply referred to as a netlist) represents the structured map of an integrated circuit (IC), detailing how various logical elements such as gates, inverters, flip-flops, and other components are interconnected. The netlist is crucial for the physical design phase of IC development, where the abstract functional design must be translated into a real, manufacturable layout. Prior to fabricating the physical IC, the netlist provides the blueprint for these interconnections and ensures that the circuit functions as intended by defining the precise paths for electrical signals. A well-optimized netlist topology considers factors like signal timing, power consumption, and area efficiency, all of which are essential for the performance and reliability of the final IC.

Logic correctness is paramount in netlist topology to ensure that the circuit operates correctly under all conditions. One common challenge is maintaining the correct polarity of signals throughout the circuit. A key building block in the netlist is the inverter which reverses the polarity of its incoming signal. However, even after optimizing the design to remove unnecessary inverter trees, individual inverters may still be required to preserve logic correctness. These inverters must be strategically placed to maintain the intended functionality of the circuit without introducing significant delays or congestion.

### SUMMARY

According to a non-limiting embodiment, a system is provided to fabricate an integrated circuit. The system generates a first netlist that includes an initial logic design defined connections between source gates, inverters, and sink gates using a total number of wires. Each of the connections establish a polarity that defines an overall polarity. The system further performs a polarity inverter removal process that removes at least one inverter from at least one connection and changes the corresponding polarity of the at least one connection from a first polarity to a second polarity. The system performs a wire placement based at least in part on the first netlist having the at least one inverter removed to build inverter trees with the overall polarity. The system further performs an inverter restoration operation that restores the first polarity of the at least one connection and produces a second netlist that reduces the overall wire length.

In another embodiment, A method of performing polarity inverter removal for reducing wire congestion in an integrated circuit (IC) is provided. The method comprises generating a first netlist that includes an initial logic design having an overall polarity defined by a plurality of connections between a plurality of source gates, a plurality of inverters, and a plurality of sink gates using a total number of wires defining an overall wire length. Each of the connections establishing a corresponding polarity that defines the overall polarity. The method further comprises performing a polarity inverter removal process that removes at least one inverter among the plurality of inverters from at least one connection among the plurality of connections and changes the corresponding polarity of the at least one connection from a first polarity to a second polarity. The method further comprises performing a wire placement based at least in part on the first netlist having the at least one inverter removed to build inverter trees with the overall polarity, and performing an inverter restoration operation that restores the first polarity of the at least one connection and produces a second netlist that reduces the overall wire length.

In yet another embodiment, a computer program product is provided. The computer program product includes a set of one or more computer-readable storage media and program instructions, collectively stored in the set of one or more storage media, for causing a processor set to perform the following computer operations. The operations comprise generating a first netlist that includes an initial logic design having an overall polarity defined by a plurality of connections between a plurality of source gates, a plurality of inverters, and a plurality of sink gates using a total number of wires defining an overall wire length. Each of the connections establishing a corresponding polarity that defines the overall polarity. The method further comprises performing a polarity inverter removal process that removes at least one inverter among the plurality of inverters from at least one connection among the plurality of connections and changes the corresponding polarity of the at least one connection from a first polarity to a second polarity. The method further comprises performing a wire placement based at least in part on the first netlist having the at least one inverter removed to build inverter trees with the overall polarity, and performing an inverter restoration operation that restores the first polarity of the at least one connection and produces a second netlist that reduces the overall wire length.

The above features and advantages, and other features and advantages, of the disclosure are readily apparent from the following detailed description when taken in connection with the accompanying drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 illustrates a computing environment according to a non-limiting embodiment of the present disclosure;

FIG. 2 is a block diagram of a system configured to fabricate an IC having a reduced wire congestion following a polarity inverter removal process according to a non-limiting embodiment of the present disclosure;

FIGS. 3A, 3B and 3C depict an example of an inverter restoration operation to establish correct logic polarity after performing a polarity inverter removal operation according to a non-limiting embodiment of the present disclosure;

FIGS. 4A, 4B and 4C depict another example of an inverter restoration operation to establish correct logic polarity after performing a polarity inverter removal operation according to a non-limiting embodiment of the present disclosure;

FIG. 5 is a flow diagram illustrating a method of performing polarity inverter removal for reducing wire congestion in an IC; and

FIG. 6 is a process flow of a method of fabricating an IC according to a non-limiting embodiments of the present disclosure.

The detailed description explains embodiments of the disclosure, together with advantages and features, by way of example with reference to the drawings.

### DETAILED DESCRIPTION

In IC chip design, “Steiner wire length” refers to the total length of wires and metal paths required to connect various components (e.g., logic gates, transistors, capacitors, resistors, etc.) in the IC. Minimizing Steiner wire length is desirable when designing an IC because shorter wiring paths generally leads to lower resistance, lower capacitance, and reduced signal propagation delay.

While inverters are a necessary logic component in netlist topology, they can significantly complicate the placement process of integrated circuits. For example, inverters can contribute to wire congestion as they often require placement in close proximity to maintain signal integrity, leading to a high concentration of routing wires in a small area. This congestion can increase delays, elevate the risk of crosstalk, and make routing more complex. Additionally, the presence of numerous inverters can degrade the overall quality of the placement result, challenging designers to achieve optimal performance and efficient use of chip area.

One or more embodiments described herein address these and other shortcomings by providing a method and system configured to perform polarity inverter removal process for reducing wire congestion and improve Steiner wire length of an IC. The polarity inverter removal includes removing polarity inverters early in the IC construction flow process, before performing global placement. When the inverters are removed the sink gates (e.g., pins of the sink gate) are marked and the owning gate is hidden from optimization (e.g., to restore the polarity in the future and prevent loss of polarity flags). This removal step allows the placement algorithms to see the true connectivity of cells. After placement and clock optimization steps, the buffering step commences to build buffer/inverter trees. As the buffer/inverter trees are built, the buffering algorithms have been enhanced to operate in the presence of these polarity flags and leverage them as needed. After buffering, inverters associated with any pins having a remaining polarity marker are restored to preserve logic correctness.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

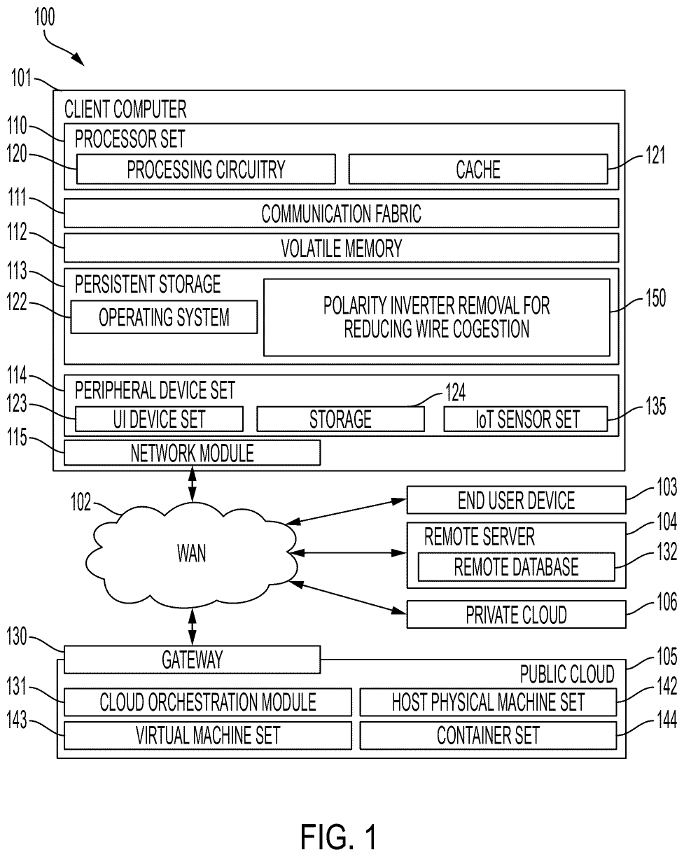

With reference now to FIG. 1 an example computing environment 100 for use in conjunction with one or more embodiments of the present disclosure is illustrated according to a non-limiting embodiment of the present disclosure. The computing environment 100 contains an example of an environment for the execution of at least some of the computer code involved in performing the inventive methods, such as performing polarity inverter removal for reducing wire congestion in an IC as shown at block 150.

In addition to block 150, computing environment 100 includes, for example, computer 101, wide area network (WAN) 102, end user device (EUD) 103, remote server 104, public Cloud 105, and private Cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IoT) sensor set 125), and network module 115. Remote server 104 includes remote database 132. Public Cloud 105 includes gateway 130, Cloud orchestration module 131, host physical machine set 142, virtual machine set 143, and container set 144.

COMPUTER 101 may take the form of a desktop computer, laptop computer, tablet computer, smart phone, smart watch or other wearable computer, mainframe computer, quantum computer, a small single board computer (e.g. a Raspberry Pi) or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a Cloud, even though it is not shown in a Cloud in FIG. 1. On the other hand, computer 101 is not required to be in a Cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 132 of remote server 104.

PUBLIC CLOUD 105 is any computer system available for use by multiple entities that provides on-demand availability of computer system resources and/or other computer capabilities, especially data storage (Cloud storage) and computing power, without direct active management by the user. Cloud computing typically leverages the sharing of resources to achieve coherence and economies of scale. The direct and active management of the computing resources of public Cloud 105 is performed by the computer hardware and/or software of Cloud orchestration module 131. The computing resources provided by public Cloud 105 are typically implemented by virtual computing environments that run on various computers making up the computers of host physical machine set 142, which is the universe of physical computers in and/or available to public Cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after the instantiation of the VCE. Cloud orchestration module 131 manages the transfer and storage of images, deploys new instantiations of VCEs, and manages active instantiations of VCE deployments. Gateway 130 is the collection of computer software, hardware, and firmware that allows public Cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public Cloud 105, except that the computing resources are only available for use by a single enterprise. While private Cloud 106 is depicted as being in communication with WAN 102, in other embodiments a private Cloud may be disconnected from the internet entirely and only accessible through a local/private network. A hybrid Cloud is a composition of multiple Clouds of different types (for example, private, community, or public Cloud types), often respectively implemented by different vendors. Each of the multiple Clouds remains a separate and discrete entity, but the larger hybrid Cloud architecture is bound together by standardized or proprietary technology that enables orchestration, management, and/or data/application portability between the multiple constituent Clouds. In this embodiment, public Cloud 105 and private Cloud 106 are both part of a larger hybrid Cloud.

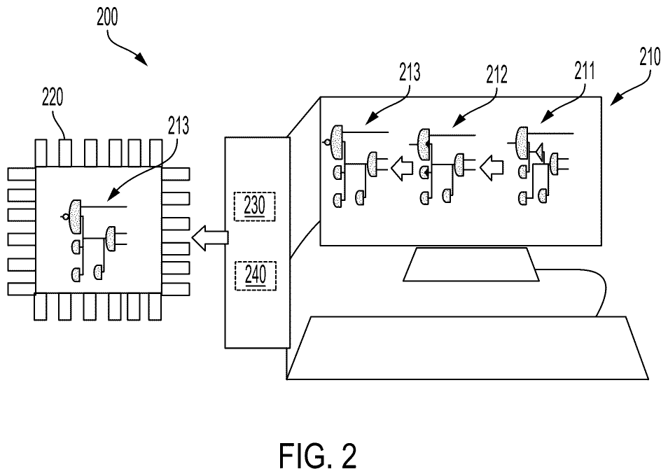

Referring now to FIG. 2, a system 200 configured to fabricate an IC having a reduced wire congestion following a polarity inverter removal process according to a non-limiting embodiment of the present disclosure. The system 200 includes processing circuitry 210 used to process a netlist that includes an initial logic design 211 having an overall polarity defined by a plurality of connections between a plurality of source gates, a plurality of inverters, and a plurality of sink gates, where each of the connections establish a local polarity that defines the overall polarity. The netlist is then utilized to finalize an IC design that is ultimately fabricated into a physical IC 220. The processing circuity 210 includes one or more processors 230 and memory 240 storing one or more software programs and code (collectively referred to as software) executable by the processor(s) 230.

The software can include, but is not limited to, computer readable program instructions for carrying out operations of the present invention, assembler instructions, instruction-set-architecture (ISA) instructions, traffic generator and simulator programs, workload traces, cache layout information, instruction and data addresses, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The memory 240 can also store computer readable program instructions, which may execute entirely on the user's computer, partly on the user's computer, as a stand-alone software package, partly on the user's computer and partly on a remote computer or entirely on the remote computer or server.

The software can also include, polarity marking and virtual optimal global placement programs, clock optimization programs, wire synthesis programs, wire placement programs, and course and/or fine optimization programs. The wire synthesis programs and/or wire placement programs can include buffer/inverter tree building software, polarity mark identification software, and polarity mark removal software. The fine optimization programs can include polarity marking inspection software and inverter restoration software.

The memory 240 can also include software that establishes an IC simulator capable of defining, capturing, and/or manipulating design specifications of an IC in a hardware description language (HDL), such as VHDL (very high speed integrated circuit hardware description language, IEEE standard 1076) or Verilog® (IEEE standard 1364; “Verilog” is a registered trade mark of Cadence Design Systems, Inc.). The resulting HDL description typically characterizes the IC at a level of abstraction, such as a register transfer level (RTL), or a behavioral level.

A compiler is used to transform the HDL description into a “compiled model” of the IC. A simulator is then used to verify proper functional operation of the compiled model according to the design specification. Once the compiled model has been functionally verified, a synthesizer is used to map the compiled model to technology-specific logic gate structures, producing a logic level “netlist.” Following further functional verification and/or timing verification, suitable positions of the logic gate structures (e.g., inverters), the type of logic gates, and the polarity of the logic gates included in the netlist relative to one another are determined.

According to one or more non-limiting embodiments, the system 200 is capable of performing perform polarity inverter removal for reducing wire congestion and improving Steiner wire length in an IC. For example, the memory 240 can store a buffering algorithm that is utilized when constructing a buffer/inverter tree on a netlist. According to a non-limiting embodiment, the buffering algorithm performs a process of strategically inserting buffer cells (or buffers) into the netlist to improve signal integrity and performance. As described herein, buffers can be used to strengthen weak signals, manage signal timing, and reduce delay by driving large capacitive loads over long distances. Accordingly, the buffering algorithm can further analyze the netlist to identify critical paths and nodes where signal degradation might occur due to factors like high fan-out (where one output drives many inputs) or long wire lengths. It then places buffers in these critical locations to ensure that signals are propagated effectively and timing constraints are met, ultimately enhancing the overall reliability and performance of the integrated circuit

After applying the buffering algorithm, the system 200 performs a polarity inverter removal process (i.e., remove one or more inverters from the netlist) early in the IC construction flow process, before performing global placement. As described herein, the global placement refers to an operation that strategically positions components on a chip layout based on algorithms that optimize for various performance metrics such as signal delay, power consumption, and chip area.

The polarity inverter removal process involves removing inverters, and marking the sink gates (e.g., pins of the sink gate) associated with the removed inverter to generate a reduced wiring congestion logic design 212. For example, polarity inverter removal process temporarily removes at least one inverter among the plurality of inverters from at least one target connection among the plurality of connections and changes the corresponding polarity of the at least one target connection from a first polarity to a second polarity. Accordingly, the owning gate is hidden from optimization (e.g., to restore the polarity in the future and prevent loss of polarity flags). This removal step allows the placement algorithms performed by the system 200 to see the true connectivity of cells as defined in the reduced wiring congestion logic design 212. After the system 200 performs virtual global placement and clock optimization operations on the reduced wiring congestion logic design 212, a buffering operation is performed to build buffer/inverter trees. The system 200 builds the buffer/inverter trees using an novel enhanced buffering algorithm, which operates in the presence of the polarity markings included in the reduced wiring congestion logic design 212. After performing the buffering operation, the system 200 performs an inverter restoration operation to generate a final logic design 213 that preserves the logic correctness of the initial logic design 211. For example, the inverter restoration operation restores the first polarity of the at least one target connection that was previously changed to a second polarity after removing one or more of the inverters connected between a source gate and a sink gate according to the polarity inverter removal process.

According to a non-limiting embodiment, the invertor restoration operation includes restoring inverters included in the initial logic design 211, which are associated with any pins having a remaining polarity marker and re-inserting any inverting paths that were not buffered after the original insertion of the polarity inverter. In another example, the inverter restoration operation can include converting a sink logic gate and/or source logic gate into a different logic function (e.g., converting an AND gate into a NAND gate). In another example, when performing the inverter restoration operation the buffering algorithm can insert polarity inverters at the source of a net when all sink are inverted. In another example, the restoration operation can include inserting a polarity inverter at the centroid for subsets of inverted sinks, where subsets are created such that every member of a subset has at least one other member within a target distance. In yet another example, the inverter restoration operation includes inserting an inverter at an output of a source gate among a plurality of source gates, and changing the logic function of a subset of sink gates among a plurality of sink gates. In this manner, the inverter can be inserted at the output of the source gate and the function of sink gates without polarity markers can be changed.

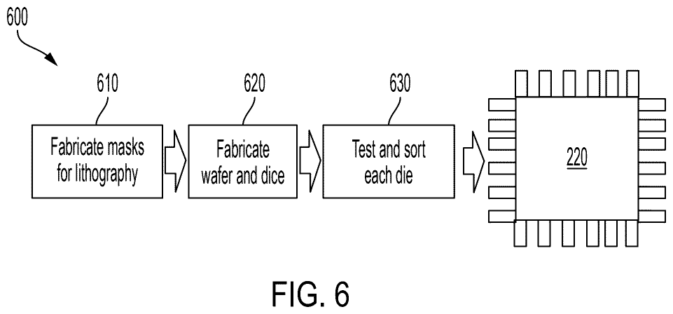

Once the final logic design 213 is generated, the physical layout of the designed IC is finalized. Masks are then generated for each layer of the IC based on the finalized physical layout, including the final logic design 213. The steps involved in the fabrication of the integrated circuit 220 are well-known and briefly described herein. The wafer is then processed in the sequence of the mask order. The processing includes photolithography and etch. This is further discussed with reference to FIG. 6.

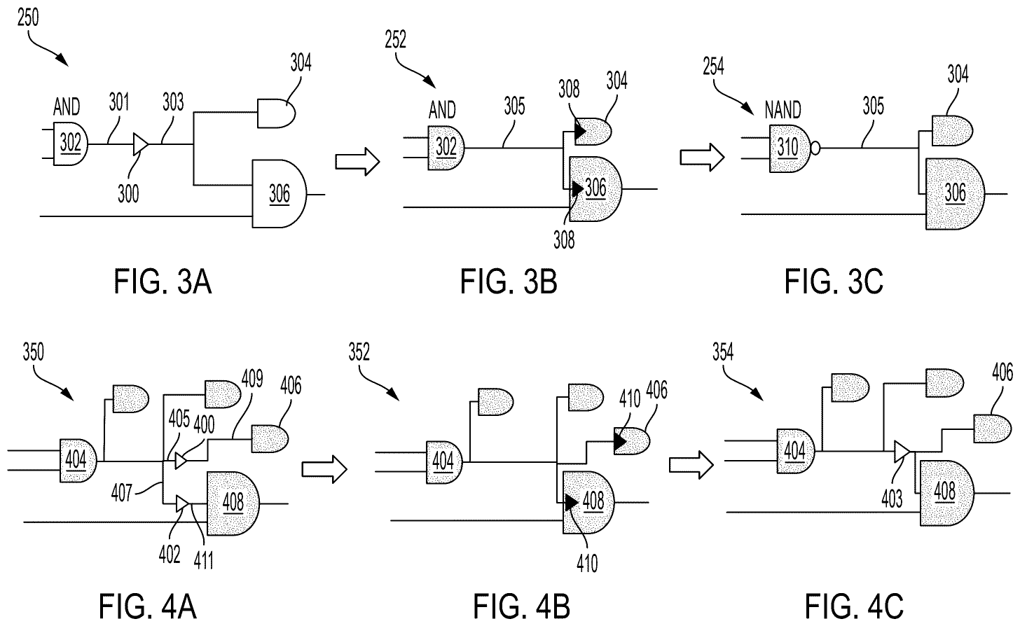

FIGS. 3A-3C illustrate an example of an inverter restoration process according to a non-limiting embodiment of the present disclosure. The inverter restoration process (e.g., performed by system 200) is applied to an initial logic design 250 defined by an IC netlist as shown in FIG. 3A. As described herein, the IC netlist includes an initial logic design 250 that includes various connections of source gates (e.g., “sources”), inverters, and sink gates (e.g., “sinks”). In this example, the initial logic design 250 includes an inverter 300 interconnected between a source gate 302 (e.g., AND gate 302) and a pair of sink gates 304 and 306. The input of the inverter 300 is connected to the output of the source gate 302 via a first wire 301, while a second wire 303 connects the output of the inverter 300 to an input of each of the first and second sink gates 304 and 306.

After performing the inverter restoration process (e.g., by the system 200), a reduced wiring congestion logic design 252 is generated as shown in FIG. 3B. In this example, the inverter restoration process involves removing the inverter 300 and adding polarity markings 308 to the sink pins (e.g., inputs) of the sink gates 304 and 306 previously connected to the inverter 300. Accordingly, the two individual wires 301 and 303 that connected the established the inverter polarity between the source gate 302 and the sink gates 304 and 306 are replaced by a single wire 305. In addition, the wire lengths used to as the inputs for the sink gates 304 and 306 are reduced.

Turning to FIG. 3C, a final logic design 254 is shown after performing a performs an inverter restoration operation. In this example, the inverter restoration operation involves replacing the initial source gate 302 with a replacement source gate 310 (e.g., a NAND gate). The replacement logic gage 310 has a different logic functionality than the initial source gate 302, but still preserves the intended logic polarity provided by the inverter 300 included in the initial logic design 250, albeit while utilizing less wires (e.g., a single wire 305 rather than two individual wires 301 and 303). Accordingly, the polarity inverter removal process reduces wire congestion of the final logic design 254 while improving the Steiner wire length of the IC design.

FIGS. 4A-4C illustrate another example of an inverter restoration process according to a non-limiting embodiment of the present disclosure. As discussed above, the inverter restoration process (e.g., performed by system 200) is applied to an initial logic design 350 defined by an IC netlist as shown in FIG. 4A. In this example, the initial logic design 350 includes first and second inverters 400 and 402. Each of the first and second inverters 400 and 402 have an input that is connected to the output of the source gate 404 via a first wire 405 and a second wire 407, respectively. A third wire 409 connects the output of the first inverter 400 to an input of each of the first sink gate 406, and a fourth wire 311 connects the output of the second inverter 402 to the second sink gate 306.

After performing the inverter restoration process (e.g., by the system 200), the reduced wiring congestion logic design 352 is generated as shown in FIG. 4B. In this example, the first inverter 400 is removed and a corresponding polarity marking 410 is added to the sink pin (e.g., input) of the first sink gate 406 previously connected to the first inverter 400. Likewise, the second inverter 402 is removed and a corresponding polarity marking 410 is added to the sink pin (e.g., input) of the second sink gate 408 previously connected to the second inverter 402. Accordingly, the number of wires needed to establish connection between the source gate 404 and the sink gates 406 and 408 are reduced. In addition, the wire lengths used to as the inputs for the first and second sink gates 406 and 408 are reduced.

Turning to FIG. 4C, a final logic design 354 is shown after performing a performs an inverter restoration operation. In this example, the inverter restoration operation involves replacing the first and second inverters 400 and 402, with a single inverter 403. Accordingly, the number of inverters and wires is reduced while still preserving the intended logic polarity provided by the inverter 300 included in the initial logic design 350. In addition, the Steiner wire length of the final log IC design 354 is improved compared to the initial logic design 350.

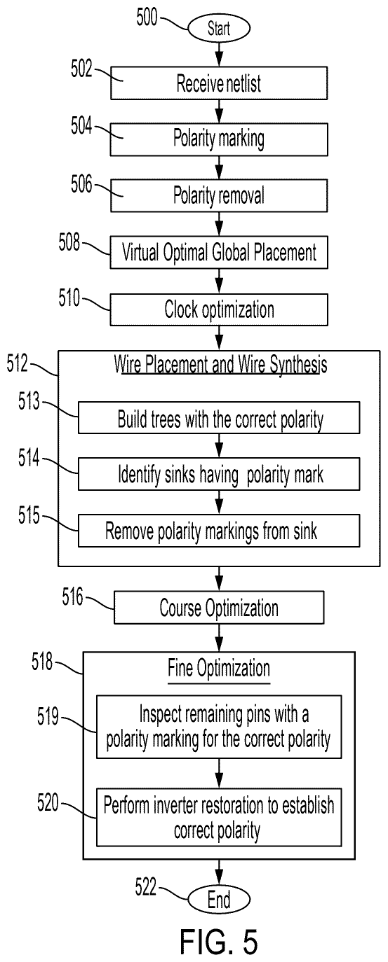

Referring now to FIG. 5, a method of performing polarity inverter removal for reducing wire congestion in an IC is illustrated according to a non-limiting embodiment. The method begins at operation 500, and a netlist is received at operation 502. The netlist represents a structured map of an IC, detailing how various logical elements such as gates, inverters, flip-flops, and other components of the IC are interconnected. At operation 504, polarity markings are performed, and inverters associated with the polarity markings are removed from the netlist at operation 506. According to a non-limiting embodiment, the operation of performing polarity markings includes identifying inverter trees in the netlist and storing as an attribute the polarity to the downstream sink from the root net.

At operation 508 a virtual optimal global placement is performed, and a clock optimization is performed at operation 510. The virtual optimal global placement can be performed by a placement algorithm that strategically positions components on a chip layout based on algorithms that optimize for various performance metrics such as signal delay, power consumption, and chip area. During this stage, the placement is performed in a virtual manner, i.e., without considering detailed physical constraints such as routing congestion or manufacturing rules to establish an initial placement that minimizes interconnect lengths and optimizes the logical and timing relationships between components. The clock optimization can involve refining the placement of clock distribution networks and related components on the integrated circuit (IC) chip layout. This process focuses on improving the timing and signal integrity of the clock signals that synchronize the operation of various components within the IC.

Turning now to operation 512, wire placement and wire synthesis are performed. The wire placement involves algorithmically determining the preliminary routing paths for interconnect wires that connect components placed on the chip. It follows virtual optimal global placement and aims to establish the initial connectivity based on logical and timing considerations while considering constraints like signal timing, area utilization, and avoiding routing congestion. The output of wire placement serves as a foundation for subsequent detailed routing (wire synthesis) where routing paths are refined to meet stringent physical design rules and optimize performance. The wire synthesis involves a process of optimizing and implementing the physical interconnects (e.g., wires or metal paths) between components (e.g., source gates, inverters, and sink gates) after the virtual optimal global placement stage. This wire synthesis can focus on translating the logical connectivity defined in the netlist into a physical layout that meets design constraints and objectives. According to a non-limiting embodiment, the wire placement and wire synthesis operation 512 includes: building trees with the correct polarity at operation 513; identifying sinks having a polarity mark at operation 514; and removing polarity markings from sink at operation 515. Thus, the wire placement and wire synthesis operation 512 implements code enhancements in the software that allow the buffering code to build trees with the correct polarity. Accordingly, any sink with a polarity mark that has its original logical function restored through the insertion of inverters will have its polarity marking removed.

Following the wire placement and wire synthesis operation 512, a course optimization process is performed at operation 516. Course optimization can include a process where the physical layout of the IC is optimized for various objectives such as timing, power, and area. The course optimization process can involve: performing Global Timing Closure to adjust buffer placements, wire lengths, and other parameters to minimize delays and ensure signal integrity; Power Optimization to tune power distribution networks and optimizing power grid design to minimize power consumption while maintaining reliability and performance; Area Utilization to optimize the use of available chip area to meet density targets and minimize chip size while accommodating all required components and routing; and Noise and Crosstalk Mitigation to address noise and crosstalk issues that may arise due to signal interactions in the IC layout.

At operation 518, a fine optimization is performed. The fine optimization operation 518 includes inspecting any remaining pins with a polarity marking for the correct polarity at operation 519, and performing inverter restoration at operation 520. The inverter restoration operation 520 is performed to establish the correct polarity intended for the IC design. After the inverter restoration operation 520 is performed, the method ends at operation 522.

Turning now to FIG. 6, a process flow 600 for fabricating the integrated circuit 220 is illustrated according to a non-limiting embodiment of the invention. Once the physical design data is obtained, based, in part, on forming improved processor frequency based on performing a polarity inverter removal process to reduce wire congestion and improve Steiner wire length of the designed IC as described herein, the integrated circuit 220 can be fabricated according to known processes that are generally described with reference to FIG. 6. Generally, a wafer with multiple copies of the final design is fabricated and cut (i.e., diced) such that each die is one copy of the integrated circuit 220. At block 610, the processes include fabricating masks for lithography (e.g., transistor masks, diode masks, and metallization masks) based on the finalized physical layout. At block 620, fabricating the wafer includes using the masks to perform photolithography and etching. Once the wafer is diced, testing and sorting each die is performed, at block 630, to filter out any faulty die before providing the fabricated integrated circuit 220.

As described herein, various embodiments of the present disclosure provide a system and method for performing polarity inverter removal to achieve reduced wire congestion in an IC.

Various embodiments are described herein with reference to the related drawings. Alternative embodiments can be devised without departing from the scope of the present disclosure. Various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the present disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about”can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A system configured to fabricate an integrated circuit (IC), the system comprising:
a memory comprising computer readable instructions; and
a processing device for executing the computer readable instructions, the computer readable instructions controlling the processing device to perform operations comprising:
generating a first netlist that includes an initial logic design having an overall polarity defined by a plurality of connections between a plurality of source gates, a plurality of inverters, and a plurality of sink gates using a total number of wires defining an overall wire length, each of the connections establishing a corresponding polarity that defines the overall polarity;
performing a polarity inverter removal process that removes at least one inverter among the plurality of inverters from at least one connection among the plurality of connections and changes the corresponding polarity of the at least one connection from a first polarity to a second polarity;
performing a wire placement based at least in part on the first netlist having the at least one inverter removed to build inverter trees with the overall polarity; and
performing an inverter restoration operation that restores the first polarity of the at least one connection and produces a second netlist that reduces the overall wire length.

2. The system of claim 1, wherein the plurality of connections between the plurality of source gates, the plurality of inverters, and the plurality of sink gates of the first netlist defines a first total wire length, and wherein the plurality of connections between the plurality of source gates, the plurality of inverters, and the plurality of sink gates of the second netlist defines a second total wire length that is less than the first total wire length.

3. The system of claim 2, further comprising fabricating a physical IC based at least in part on the second netlist.

4. The system of claim 3, wherein performing a polarity inverter removal process comprises:
applying a polarity marking to at least one sink gate connected to the at least one inverter;
removing the at least one inverter connected between a source gate and the at least one sink gate having the polarity marking; and
directly connecting the source gate to the at least one sink gate having the polarity marking.

5. The system of claim 4, wherein the inverter restoration operation includes restoring an inverter among the at least one inverter removed according to the polarity inverter removal process.

6. The system of claim 4, wherein the inverter restoration operation includes changing a logic function of one or both of the source gate and the at least one sink gate having the polarity marking.

7. The system of claim 4, wherein the inverter restoration operation includes inserting at least one inverter at an output of the source gate when each sink gate among the at least one sink gate has the polarity marking.

8. The system of claim 3, wherein the inverter restoration operation includes:
inserting an inverter at an output of a source gate among the plurality of source gates; and
changing a logic function of a subset of sink gates among the plurality of sink gates.

9. A method of performing polarity inverter removal for reducing wire congestion in an integrated circuit (IC), the method comprising:
generating a first netlist that includes an initial logic design having an overall polarity defined by a plurality of connections between a plurality of source gates, a plurality of inverters, and a plurality of sink gates using a total number of wires defining an overall wire length, each of the connections establishing a corresponding polarity that defines the overall polarity;
performing a polarity inverter removal process that removes at least one inverter among the plurality of inverters from at least one connection among the plurality of connections and changes the corresponding polarity of the at least one connection from a first polarity to a second polarity;
performing a wire placement based at least in part on the first netlist having the at least one inverter removed to build inverter trees with the overall polarity; and
performing an inverter restoration operation that restores the first polarity of the at least one connection and produces a second netlist that reduces the overall wire length.

10. The method of claim 9, wherein the plurality of connections between the plurality of source gates, the plurality of inverters, and the plurality of sink gates of the first netlist defines a first total wire length, and wherein the plurality of connections between the plurality of source gates, the plurality of inverters, and the plurality of sink gates of the second netlist defines a second total wire length that is less than the first total wire length.

11. The method of claim 10, further comprising fabricating a physical IC based at least in part on the second netlist.

12. The method of claim 11, wherein performing the polarity inverter removal process comprises:
applying a polarity marking to at least one sink gate connected to the at least one inverter;
removing the at least one inverter connected between a source gate and the at least one sink gate having the polarity marking; and
directly connecting the source gate to the at least one sink gate having the polarity marking.

13. The method of claim 12, wherein the inverter restoration operation includes restoring an inverter among the at least one inverter removed according to the polarity inverter removal process.

14. The method of claim 12, wherein the inverter restoration operation includes changing a logic function of one or both of the source gate and the at least one sink gate having the polarity marking.

15. The method of claim 12, wherein the inverter restoration operation includes inserting at least one inverter at an output of the source gate when each sink gate among the at least one sink gate has the polarity marking.

16. The method of claim 11, wherein the inverter restoration operation includes:
inserting an inverter at an output of a source gate among the plurality of source gates; and
changing a logic function of a subset of sink gates among the plurality of sink gates.

17. A computer program product to control a system to perform polarity inverter removal for reducing wire congestion in an integrated circuit (IC), the computer program product comprising a computer readable storage medium having program instructions embodied therewith, the program instructions executable by an electronic computer processor to control the system to perform operations comprising:
generating a first netlist that includes an initial logic design having an overall polarity defined by a plurality of connections between a plurality of source gates, a plurality of inverters, and a plurality of sink gates using a total number of wires defining an overall wire length, each of the connections establishing a corresponding polarity that defines the overall polarity;
performing a polarity inverter removal process that removes at least one inverter among the plurality of inverters from at least one connection among the plurality of connections and changes the corresponding polarity of the at least one connection from a first polarity to a second polarity;
performing a wire placement based at least in part on the first netlist having the at least one inverter removed to build inverter trees with the overall polarity; and
performing an inverter restoration operation that restores the first polarity of the at least one connection and produces a second netlist that reduces the overall wire length.

18. The computer program product of claim 17, wherein the plurality of connections between the plurality of source gates, the plurality of inverters, and the plurality of sink gates of the first netlist defines a first total wire length, and wherein the plurality of connections between the plurality of source gates, the plurality of inverters, and the plurality of sink gates of the second netlist defines a second total wire length that is less than the first total wire length.

19. The computer program product of claim 18, further comprising fabricating a physical IC based at least in part on the second netlist.

20. The computer program product of claim 19, wherein performing the polarity inverter removal process comprises:
applying a polarity marking to at least one sink gate connected to the at least one inverter;
removing the at least one inverter connected between a source gate and the at least one sink gate having the polarity marking; and
directly connecting the source gate to the at least one sink gate having the polarity marking; and
wherein the inverter restoration operation includes restoring an inverter among the at least one inverter removed according to the polarity inverter removal process.
